(19) United States
(12) Patent Application Publication
(10) Pub. No.: US 2025/0079155 A1
(43) Pub. Date: Mar. 6, 2025

(54) HAFNIUM-CONTAINING STRUCTURES AND RELATED METHODS AND SYSTEMS

(71) Applicant: ASM IP Holding B.V., Almere (NL)

(72) Inventors: Fatemeh Davodi, Helsinki (FI); David Kurt de Roest, Leuven (BE)

(21) Appl. No.: 18/814,784

(22) Filed: Aug. 26, 2024

Related U.S. Application Data
(60) Provisional application No. 63/535,271, filed on Aug. 29, 2023.

(51) Int. Cl. H01L 21/02

(52) U.S. Cl. CPC H01L 21/02181; H01L 21/02205; H01L 21/0228

(57) ABSTRACT

Methods, systems, and structures for lithography, in particular EUV lithography. Embodiments of structures disclosed herein comprise a hafnium oxide secondary electron generation layer which can advantageously reduce the dose requirement to fully develop EUV resist.

### CROSS-REFERENCE TO RELATED APPLICATION(S)

This application claims the benefit of U.S. Provisional Application 63/535,271 filed on Aug. 29, 2023, the entire contents of which are incorporated herein by reference.

### FIELD OF INVENTION

The present disclosure is in the field of integrated circuit manufacture, in particular in the field of Front-end-of-Line Patterning, more particular in the field of extreme ultraviolet (EUV) patterning.

### BACKGROUND OF THE DISCLOSURE

Semiconductor device patterning is often designed around the properties of expensive lithography equipment. Reducing the time needed per wafer during lithography steps can greatly improve throughput and costs of device fabrication, and this time can be expressed in terms of lithography dose.

Dose is equated to energy over a unit space, or in other terms, to the photon flux (number of photons per unit time per unit space) multiplied by the photon energy and exposure time. In the emerging field of extreme ultraviolet (EUV) lithography, which improves resolution through decreased wavelength, the energy per photon is greatly increased. To reduce the dose, either the photon flux or the exposure time needs to be decreased, both of which reduces the total number of photons hitting the lithography resists to very low amounts. Moreover, high energy EUV photons are more difficult to absorb by most materials, exaggerating the issue of the low photon count. With such a low number of photons absorbed by the resist, it is difficult to obtain a good quality lithography structure due to the photon shot noise effect, especially at the small structure sizes being pursued. Therefore, the key to practically decreasing dose is to increase the useful effect of each photon.

The usefulness of each photon is commonly improved through two ways: by increasing the absorption of each photon, and by increasing the number of electrons produced per photon. Absorption is often improved by simply inserting EUV absorbing materials into the lithography structure. This absorption produces photoelectrons which can cause reactions in the resist, but one electron per photon conversion still produces high shot noise. This problem is solved if the high energy photoelectrons are converted into multiple secondary electrons (SEs) through multiple possible pathways.

There are two main known solutions to incorporating EUV absorbing and SE producing materials into the lithography stack. One is to directly add the materials to the resist such as by adding sensitizers to chemically amplified resists (CARs) or by using highly absorbing metal oxide resists (MORs). However, there are drawbacks to these new resists. Resists have become complicated structures that are difficult to control SE generation, and too high absorption in the resist can block further photons from traveling to the bottom of the resist where needed. Too long of electron path in the resist is also not desired as this will hurt resolution and cause roughness. If absorption is balanced so photons absorb at the resist bottom, SEs are still often lost to the substrate.

The second solution to compliment the above solution is to deposit the EUV absorbing and SE producing materials into the secondary electron generation layers. These layers can be directly designed to produce many electrons and help to supply SEs to the resist bottom. However, many of the materials are heavy metals with self-limiting effects because electrons from deeper levels cannot easily move to the resist. For example, tin is a common candidate for high EUV absorption, but it suffers from the above-mentioned limitations which have so far not reach ideal levels of dose reduction. Thus, there is still a need for alternative materials which have higher absorption and allow improved electron paths to the resist.

### SUMMARY OF THE DISCLOSURE

Described herein is a structure comprising a substrate, a secondary electron generation layer, and an extreme ultraviolet (EUV) resist. The secondary electron generation layer is disposed between the substrate and the EUV resist. The secondary electron generation layer comprises hafnium. In some embodiments, the secondary electron generation layer comprises hafnium oxide (HfO2).

In some embodiments, the secondary electron generation layer has a thickness of at least 1 nm to at most 5 nm.

In some embodiments, the secondary electron generation layer further comprises one or more EUV absorbing elements selected from the list consisting of iodine (I), tellurium (Te), cesium (Cs), antimony (Sb), tin (Sn), indium (In), bismuth (Bi), silver (Ag), lead (Pb), gold (Au), platinum (Pt), iridium (Ir), manganese (Mn), iron (Fe), cobalt (Co), nickel (Ni), copper (Cu), zinc (Zn), gallium (Ga), germanium (Ge), and arsenic (As).

In some embodiments, the secondary electron generation layer contains at least 15 atomic percent hafnium.

In some embodiments, the structure further comprises a glue layer positioned between the secondary electron generation layer and the EUV resist.

In some embodiments, the glue layer comprises silicon, carbon, oxygen, and hydrogen.

In some embodiments, the glue layer further comprises nitrogen.

Further described herein is a method of forming a structure, the method comprising providing a substrate to a reaction chamber; executing a deposition process that comprises exposing the substrate to a hafnium precursor comprising hafnium, the deposition process further comprising exposing the substrate to a reactant, thereby forming a hafnium-containing secondary electron generation layer on the substrate; and, forming an EUV resist on the substrate.

In some embodiments, the deposition process comprises a cyclical deposition process, the cyclical deposition process comprising a plurality of cycles, ones from the plurality of cycles comprising a hafnium precursor pulse and a reactant pulse, the hafnium precursor pulse comprising exposing the substrate to the hafnium precursor, the reactant pulse comprising exposing the substrate to the reactant, thereby forming a hafnium-containing secondary electron generation layer on the substrate.

In some embodiments, the method further comprises forming a glue layer on the substrate, wherein the glue layer is formed on the hafnium-containing secondary electron generation layer, and wherein the EUV resist is formed on the glue layer.

In some embodiments, the hafnium precursor comprises one or more alkylamine ligands.

In some embodiments, the hafnium precursor comprises tetrakis(ethylmethylamino)hafnium.

In some embodiments, the reactant comprises an oxygen reactant, the oxygen reactant comprising oxygen.

In some embodiments, the oxygen reactant comprises ozone.

In some embodiments, the oxygen reactant comprises water.

In some embodiments, the deposition process further comprises generating a plasma and exposing the substrate to one or more active species generated in the plasma.

In some embodiments, exposing the substrate to one or more active species generated in the plasma occurs at least partially simultaneously with the reactant pulse and wherein the reactant comprises the one or more active species, the active species comprising at least one of ions and radicals.

In some embodiments, the deposition process occurs thermally.

In some embodiments, ones from the plurality of cycles further comprise an EUV absorbing element pulse, the EUV absorbing element pulse comprising exposing the substrate to an EUV absorbing element precursor, wherein the EUV absorbing element precursor comprises an EUV absorbing element selected from the list consisting iodine (I), tellurium (Te), cesium (Cs), antimony (Sb), tin (Sn), indium (In), bismuth (Bi), silver (Ag), lead (Pb), gold (Au), platinum (Pt), iridium (Ir), manganese (Mn), iron (Fe), cobalt (Co), nickel (Ni), copper (Cu), zinc (Zn), gallium (Ga), germanium (Ge), and arsenic (As).

In some embodiments, the controller is constructed and arranged for causing the system to execute a method as described herein.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIGS. 1-3 show embodiments of structures according to the present disclosure.

FIG. 4 shows an embodiment of a method according to the present disclosure.

FIGS. 5-8 show embodiments of systems according to the present disclosure.

FIG. 9 shows an embodiment of a method according to the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gasses. Exemplary seal gasses include noble gasses, nitrogen, and the like. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may comprise, or may consist at least partially of, a plurality of dispersed atoms on a surface of a substrate and/or may be or may become embedded in a substrate and/or may be or may become embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices. A film or layer may be selectively grown on some parts of a substrate, and not on others.

The term “deposition process” as used herein can refer to the introduction of precursors (and/or reactants) into a reaction chamber to deposit a layer over a substrate. “Cyclical deposition processes” are examples of “deposition processes”.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). A pulse can comprise exposing a substrate to a precursor or reactant. This can be done, for example, by introducing a precursor or reactant to a reaction chamber in which the substrate is present. Additionally or alternatively, exposing the substrate to a precursor can comprise moving the substrate to a location in a substrate processing system in which the reactant or precursor is present.

Generally, for ALD processes, during each cycle, a precursor is introduced into a reaction chamber and is chemisorbed onto a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term “purge” may refer to a procedure in which an inert or substantially inert gas is provided to a reaction chamber in between two pulses of gasses that react with each other. For example, a purge, e.g. using a noble gas, may be provided between a precursor pulse and a reactant pulse, thus avoiding or at least minimizing gas phase interactions between the precursor and the reactant. It shall be understood that a purge can be effected either in time or in space, or both. For example, in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied.

As used herein, a “precursor” includes a gas or a material that can become gaseous and that can be represented by a chemical formula that includes an element which may be incorporated during a deposition process as described herein.

The term “oxygen reactant” can refer to a gas or a material that can become gaseous and that can be represented by a chemical formula that includes oxygen. In some cases, the chemical formula includes oxygen and hydrogen.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like.

As used herein, the term “comprising” indicates that certain features are included, but that it does not exclude the presence of other features, as long as they do not render the claim or embodiment unworkable. In some embodiments, the term “comprising” includes “consisting”. As used herein, the term “consisting” indicates that no further features are present in the apparatus/method/product apart from the ones following said term. When the term “consisting” is used referring to a chemical compound, it indicates that the chemical compound only contains the components which are listed.

The term “dose” as used herein can refer to an amount of photon energy provided to a substrate per unit area, or in other terms, to the photon flux (number of photons per unit time per unit space) multiplied by the photon energy and exposure time.

Described herein is a structure that comprises a substrate, a secondary electron generation layer, and an extreme ultraviolet (EUV) resist. The secondary electron generation layer is positioned between the substrate and the EUV resist. The secondary electron generation layer can comprise hafnium, which can advantageously reduce the dose requirement to fully develop EUV resist. In some embodiments, the secondary electron generation layer comprises hafnium oxide (HfO₂). In some embodiments, the secondary electron generation layer comprises a hafnium chalcogenide such as hafnium selenide, hafnium sulfide, or hafnium telluride. In some embodiments, the secondary electron generation layer comprises a hafnium pnictogen such as hafnium nitride, hafnium phosphide, hafnium arsenide, or hafnium antimonide. In some embodiments, the secondary electron generation layer comprises hafnium boride. In some embodiments, the secondary electron generation layer comprises hafnium oxide (HfO₂). In some embodiments, the secondary electron generation layer substantially consists of hafnium oxide. Surprisingly and advantageously, a secondary electron generation layer comprising hafnium oxide was found to allow reducing the dose requirement of chemically amplified resist by 5 percent. Without the present disclosure being limited by any particular theory or mode of operation, it is believed that, while hafnium oxide is not a particularly strong EUV absorber, it shows excellent secondary electron yield, which can explain the observed dose reduction.

Exemplary structures according to embodiments of the present disclosure are shown in FIGS. 1 to 3.

FIG. 1 shows a structure that comprises a substrate 100, a secondary electron generation layer 120 overlying the substrate 100, and a resist 140 overlying the secondary electron generation layer 120.

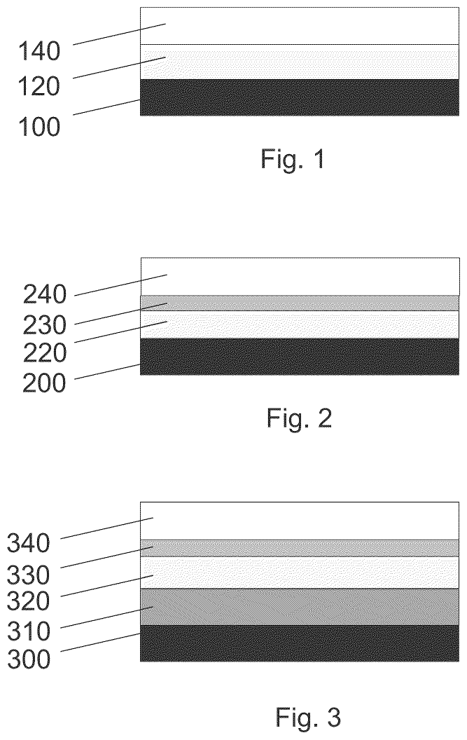

FIG. 2 shows a structure that comprises a substrate 200, a secondary electron generation layer 220 overlying the substrate 200, a glue layer 230 overlying the secondary electron generation layer 220, and a resist 240 overlying the glue layer 230. Advantageously, the glue layer 230 can provide adhesion between the secondary electron generation layer 220 and the resist 240. Exemplary glue layers and methods of their manufacture are described in U.S. patent Ser. No. 11/735,422 which is incorporated herein by reference in its entirety.

FIG. 3 shows a structure that comprises a substrate 300, an electron reflecting layer 310 overlying the substrate, a secondary electron generation layer 320 overlying the electron reflecting layer 310, a glue layer 330 overlying the secondary electron generation layer 320, and a resist 340 overlying the glue layer 330. Advantageously, the electron reflection layer 310 can reflect electrons generated in the secondary electron generation layer 320, which can lead to additional dose reduction. Suitable electron reflection layers 310 and methods of their manufacture are described in U.S. provisional application No. 63/484,346 which is incorporated herein by reference in its entirety.

In some embodiments, the secondary electron generation layer has a thickness of less than 10 nm, or of at least 1 nm to at most 5 nm, or of at least 2 nm to at most 4 nm, or of about 3 nm.

In some embodiments, the secondary electron generation layer further comprises one or more EUV absorbing elements. In some embodiments, the one or more EUV absorbing elements are selected from the list consisting of iodine (I), tellurium (Te), cesium (Cs), antimony (Sb), tin (Sn), indium (In), bismuth (Bi), silver (Ag), lead (Pb), gold (Au), platinum (Pt), iridium (Ir), manganese (Mn), iron (Fe), cobalt (Co), nickel (Ni), copper (Cu), zinc (Zn), gallium (Ga), germanium (Ge), and arsenic (As). Exemplary precursors for one or more of these elements are described one or more of U.S. patent application Ser. Nos. 17/900,065, 17/900,578, 17/899,928, which are incorporated by reference herein in their entirety.

In some embodiments, the one or more EUV absorbing elements are selected from tin and tellurium.

In some embodiments, the secondary electron generation layer can comprise one or more elements selected from magnesium, tin, and aluminum. For example, the secondary electron generation layer can comprise one or more materials selected from the list consisting of magnesium oxide, antimony oxide, and tin oxide. Magnesium oxide can comprise MgO. Antimony oxide can comprise SbO. Tin oxide can comprise SnO, i.e. tin(II) oxide.

In some embodiments, the secondary electron generation layer comprises a chalcogenide such as sulfur, selenium, or tellurium. For example, the secondary electron generation layer can comprise a metal chalcogenide such as one or more of MgS, SbS, SnS, MgSe, SbSe, SnSe, MgTe, SbTe, or SnTe.

In some embodiments, the secondary electron generation layer contains at least 5, 10, 15, 20, 30, 40, 50, 60, 70, 80, or 90 atomic percent hafnium.

In some embodiments, the structure further comprises a glue layer. The glue layer can be positioned between the secondary electron generation layer and the EUV resist. In some embodiments, the glue layer comprises silicon, carbon, oxygen, and hydrogen. In some embodiments, the glue layer further comprises nitrogen. In some embodiments, the glue layer comprises silicon, oxygen, and carbon. In some embodiments, the glue layer can comprise silicon oxycarbide. In some embodiments, the glue layer can further comprise nitrogen. In some embodiments, the glue layer can comprise silicon oxycarbonitride. In some embodiments, the glue layer further comprises hydrogen. The glue layer can be formed using a thermal or a plasma vapor phase deposition process. For example, the glue layer can be formed by means of thermal or plasma-enhanced atomic layer deposition.

In some embodiments, the EUV resist is selected from a metalorganic framework resist, a metal oxide resist, and a chemically amplified resist. The resist can be positive or negative tone.

Further described herein is a method of forming a structure. The method can comprise providing a substrate to a reaction chamber. The method can further comprise executing a deposition process that comprises exposing the substrate to a hafnium precursor comprising hafnium. The deposition process can further comprise exposing the substrate to a reactant. Thus, a hafnium-containing secondary electron generation layer can be formed on the substrate. A method as described herein can further comprise forming an EUV resist on the substrate.

In some embodiments, the deposition process comprises a cyclical deposition process. Thus, an embodiment of a method as described herein can be described as follows: The method can comprise providing a substrate to a reaction chamber. The method can further comprise executing a cyclical deposition process. The cyclical deposition process can comprise a plurality of cycles. Ones from the plurality of cycles comprise a hafnium precursor pulse and a reactant pulse. The hafnium precursor pulse comprises exposing the substrate to a hafnium precursor. The reactant pulse comprises exposing the substrate to a reactant. The hafnium precursor comprises hafnium. Thus, a hafnium-containing secondary electron generation layer is formed on the substrate. The method can further comprise forming an EUV resist on the substrate.

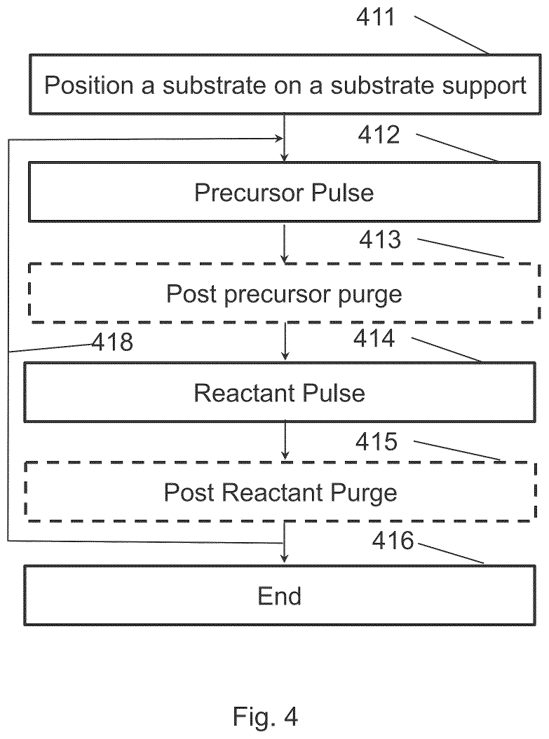

An exemplary ALD pulsing scheme is shown in FIG. 4. Such a pulsing scheme can be suitable used for forming binary materials such as hafnium oxide. In particular, the embodiment of FIG. 4 comprises a step 411 of positioning a substrate on a substrate support, after which a plurality of deposition cycles 418 are executed. Ones from the plurality of deposition cycles 418 comprise a precursor pulse 412 and a reactant pulse 414. Optionally, precursor pulses 412 can be followed by post precursor purges 413. Optionally, reactant pulses 414 can be followed by post reactant purges 415. After a suitable amount of deposition cycles 418 have been executed, a layer has been formed on the substrate, and the method ends 416.

In some embodiments, a method as described herein can comprise forming a glue layer on the substrate. The glue layer can be formed on the hafnium-containing secondary electron generation layer. The EUV resist can be formed on the glue layer. Thus, the glue layer can enhance adhesion between the secondary electron generation layer and the EUV resist.

In some embodiments, the hafnium precursor comprises one or more alkylamine ligands. In some embodiments, the hafnium precursor comprises tetrakis(ethylmethylamino)hafnium.

In some embodiments, the hafnium precursor comprises Hafnium in a +4 oxidation state.

In some embodiments, the hafnium precursor comprises one or more ligands selected from alkylamido ligands, alkoxy ligands, cyclopentadienyl ligands, beta-diketonate ligands, alkyl ligands, amidinate ligands, and halide ligands.

In some embodiments, the hafnium precursor can comprise at least one of an alkylamido ligand and a dialkylamido ligand. Suitable hafnium alkylamines include tetrakis(dimethylamino)hafnium, tetrakis(diethylamino)hafnium, and tetrakis(ethylmethylamino)hafnium.

In some embodiments, the hafnium precursor comprises a hafnium halide such as a hafnium chloride, a hafnium bromide, or a hafnium iodide. Suitable hafnium chlorides include HfCl₄. Suitable hafnium bromides include HfBr₄. Suitable hafnium iodides include HfI₄.

In some embodiments, the hafnium precursor comprises a heteroleptic hafnium precursor. In some embodiments, the heteroleptic hafnium precursor comprises an unsubstituted or an alkyl-substituted hafnium cyclopentadienyl ligand. In some embodiments, the hafnium precursor comprises one or more alkylamido ligands. In some embodiments, the hafnium precursor comprises an alkylamido ligand and an unsubstituted or an alkyl-substituted cyclopentadienyl ligand. Suitable hafnium precursors include HfCp(NMe₂)₃, i.e. Tris(dimethylamino)cyclopentadienyl Hafnium.

In some embodiments, the reactant comprises an oxygen reactant. The oxygen reactant comprises oxygen. In some embodiments, the oxygen reactant comprises ozone. In some embodiments, the oxygen reactant comprises water.

In some embodiments, the oxygen reactant comprises one or more of H₂O, H₂O₂, O₂, O₃, N₂O, NO, and NO₂.

In some embodiments, the reactant comprises a chalcogen reactant. Suitable chalcogen reactants can include sulfur reactants such as H₂S, selenium reactants such as H₂Se, and tellurium reactants such as H₂Te.

In some embodiments, the reactant comprises a pnictogen reactant. Suitable pnictogen reactants can include nitrogen reactants such as NH₃, phosphorous reactants such as PH₃, arsenic reactants such as AsH₃, and antimony reactants such as SbH₃.

In some embodiments, the reactant comprises a boron reactant. Suitable boron reactants include boron hydrides such as B₂H₆.

In some embodiments, ones from the plurality of cycles further comprise generating a plasma and exposing the substrate to one or more active species generated in the plasma.

In some embodiments, exposing the substrate to one or more active species generated in the plasma occurs at least partially simultaneously with the reactant pulse. In some embodiments, exposing the substrate to one or more active species generated in the plasma occurs during the reactant pulse. In such a case, the reactant can comprise the one or more active species. In some embodiments, the active species comprise at least one of ions and radicals, e.g. at least one of oxygen ions and oxygen radicals.

In some embodiments, the deposition process, e.g. cyclical deposition process, occurs thermally. In other words, and in some embodiments, the deposition process, e.g. cyclical deposition process, does not comprise exposing the substrate to active species such as ions or radicals that may be generated in a plasma.

In some embodiments, ones from the plurality of cycles further comprise an EUV absorbing element pulse. The EUV absorbing element pulse comprises exposing the substrate to an EUV absorbing element precursor. The EUV absorbing element precursor comprises an EUV absorbing element selected from the list consisting of iodine (I), tellurium (Te), cesium (Cs), antimony (Sb), tin (Sn), indium (In), bismuth (Bi), silver (Ag), lead (Pb), gold (Au), platinum (Pt), iridium (Ir), manganese (Mn), iron (Fe), cobalt (Co), nickel (Ni), copper (Cu), zinc (Zn), gallium (Ga), germanium (Ge), and arsenic (As). In some embodiments, the EUV absorbing element selected from tin and tellurium.

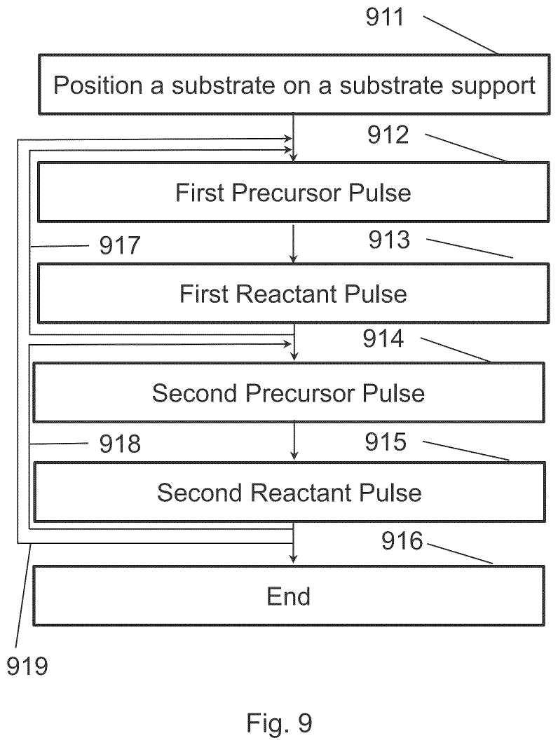

FIG. 9 shows an ALD pulsing scheme that can be advantageously used for forming ternary materials such a hafnium oxide containing secondary electron generation layer that comprises one or more EUV absorbing elements as described herein. In particular, the embodiment of FIG. 9 comprises a step 911 of positioning a substrate on a substrate support, after which a plurality of deposition cycles 919 are executed. Ones from the plurality of deposition cycles 918 comprise a first sub cycle 917 and a second sub cycle 918. Optionally, the first sub cycle 917, can be repeated one or more times. Optionally, the second sub cycle 918 can be repeated one or more times. The first sub cycle 917 comprises a first precursor pulse 912 and a first reactant pulse 913. The first precursor pulse 912 comprises exposing the substrate to a first precursor. The first reactant pulse 913 comprises exposing the substrate to a first reactant 914. The second sub cycle comprises a second precursor pulse 914 and a second reactant pulse 915. The second precursor pulse 914 comprises exposing the substrate to a second precursor. The second reactant pulse 915 comprises exposing the substrate to a second reactant 915. After a suitable amount of deposition cycles 918 have been executed, a layer has been formed on the substrate, and the method ends 916. Subsequent pulses may be optionally separated by a purge.

In some embodiments, the first precursor and the second precursor are different. In some embodiments, the first reactant and the second reactant are different. For example, in order to form magnesium aluminum oxide, the first precursor may be a magnesium precursor, and the first and second reactants may be oxygen reactants.

In a specific embodiment, the hafnium oxide layer can have a thickness of 3 nm or less, e.g. a thickness of 1 nm or 2 nm. The hafnium oxide layer can be employed as a secondary electron generation layer under an EUV resist. The secondary electron generation layer can absorb EUV radiation and can generate secondary electrons. The secondary electron generation layer can be formed using a thermal cyclical deposition process such as atomic layer deposition (ALD). Suitable hafnium precursors include hafnium alkylamines such as tetrakis(ethylmethylamino)hafnium (TEMAH). An oxygen reactant such as ozone or water can be employed as a reactant. The thermal cyclical deposition process can be carried out in the temperature range of 175-275° C. It shall be understood that depositing hafnium oxide in this way is, as such, known. Such a secondary electron generation layer can be employed in any one of the configurations of FIGS. 1 to 3.

Further described herein is a system that comprises a reaction chamber and a controller. The controller is constructed and arranged for causing the system to execute a method as described herein.

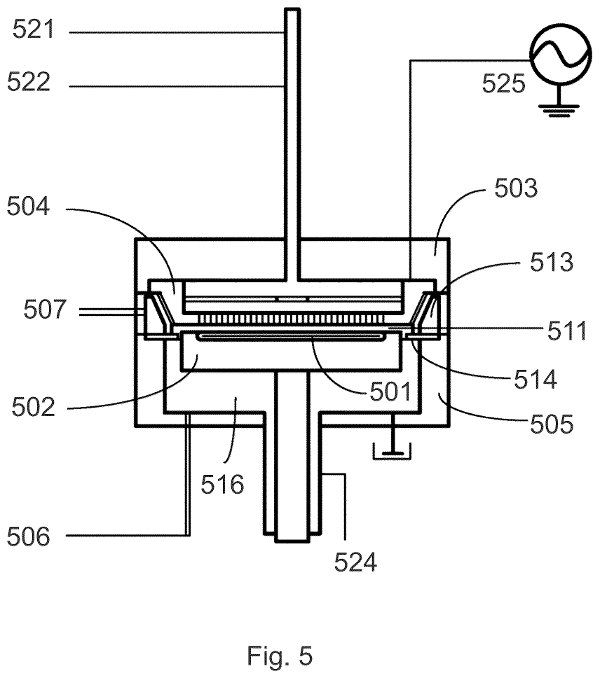

Layers formed in methods according to the present disclosure may be formed in any suitable apparatus, including in a reactor as shown in FIG. 5. Similarly, the presently provided structures or parts thereof may be manufactured in any suitable apparatus, including a reactor as shown in FIG. 5. FIG. 5 is a schematic view of a plasma-enhanced atomic layer deposition (PEALD) apparatus, desirably in conjunction with controls programmed to conduct the sequences described below, usable in some embodiments of the present disclosure. In this figure, by providing a pair of electrically conductive flat-plate electrodes 502, 504 in parallel and facing each other in the interior 511 (reaction zone) of a reaction chamber 503, applying RF power (e.g. at 13.56 MHz and/or 27 MHz) from a power source 525 to one side, and electrically grounding the other side 512, a plasma is excited between the electrodes. A temperature regulator may be provided in a lower stage 502, i.e. the lower electrode. A substrate 501 is placed thereon and its temperature is kept constant at a given temperature. The upper electrode 504 can serve as a shower plate as well, and a reactant gas and/or a dilution gas, if any, as well as a precursor gas can be introduced into the reaction chamber 503 through a gas line 521 and a gas line 522, respectively, and through the shower plate 504. Additionally, in the reaction chamber 503, a circular duct 513 with an exhaust line 517 is provided, through which the gas in the interior 511 of the reaction chamber 503 is exhausted. Additionally, a transfer chamber 505 is disposed below the reaction chamber 503 and is provided with a gas seal line 524 to introduce seal gas into the interior 511 of the reaction chamber 503 via the interior 516 of the transfer chamber 505 wherein a separation plate 514 for separating the reaction zone and the transfer zone is provided. Note that a gate valve through which a wafer may be transferred into or from the transfer chamber 505 is omitted from this figure. The transfer chamber is also provided with an exhaust line 506. In some embodiments, forming the secondary electron generation layer, optionally forming the glue layer, and forming the EUV resist are done in one and the same reaction chamber. In some embodiments, forming one or more of these layers are formed in separate reaction chambers comprised in one cluster system in which substrates are transferable from one reaction chamber to another without breaking vacuum, or without exiting an inert gas environment.

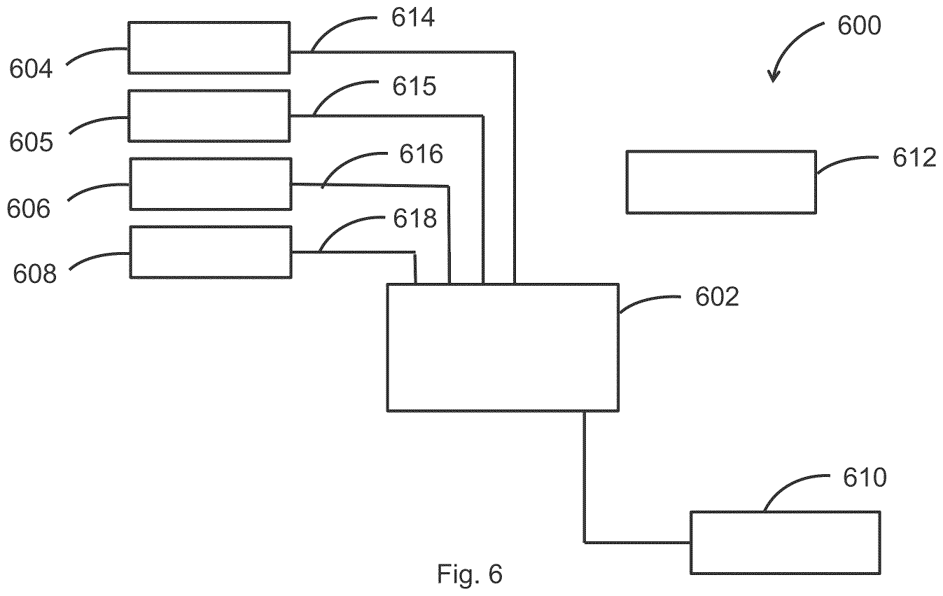

FIG. 6 illustrates a system 600 in accordance with exemplary embodiments of the disclosure. The system 600 can be used to perform a method as described herein and/or form a structure or device portion as described herein.

In the illustrated example, the system 600 includes one or more reaction chambers 602, a first precursor gas source 604, a reactant gas source 606, a purge gas source 608, an exhaust 610, and a controller 612.

The reaction chamber 602 can include any suitable reaction chamber, such as an ALD or CVD reaction chamber.

The first precursor gas source 604 can include a vessel and one or more precursors as described herein-alone or mixed with one or more carrier (e.g., noble) gases. The reactant gas source 606 can include a vessel and one or more reactants as described herein-alone or mixed with one or more carrier gases. The purge gas source 608 can include one or more noble gases as described herein. Although illustrated with four gas sources 604-608, the system 600 can include any suitable number of gas sources. The gas sources 604-608 can be coupled to reaction chamber 602 via lines 614-618, which can each include flow controllers, valves, heaters, and the like.

The exhaust 610 can include one or more vacuum pumps.

The controller 612 includes electronic circuitry and software to selectively operate valves, manifolds, heaters, pumps and other components included in the system 600. Such circuitry and components operate to introduce precursors and purge gases from the respective sources 604-608. The controller 612 can control timing of gas pulse sequences, temperature of the substrate and/or reaction chamber, pressure within the reaction chamber, and various other operations to provide proper operation of the system 600. The controller 612 can include control software to electrically or pneumatically control valves to control flow of precursors, reactants and purge gases into and out of the reaction chamber 602. The controller 612 can include modules such as a software or hardware component, e.g., a FPGA or ASIC, which performs certain tasks. A module can advantageously be configured to reside on the addressable storage medium of the control system and be configured to execute one or more processes.

Other configurations of the system 600 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber 602. Further, as a schematic representation of a system, many components have been omitted for simplicity of illustration, and such components may include, for example, various valves, manifolds, purifiers, heaters, containers, vents, and/or bypasses.

During operation of the reactor system 600, substrates, such as semiconductor wafers (not illustrated), are transferred from, e.g., a substrate handling system to the reaction chamber 602. Once substrate(s) are transferred to the reaction chamber 602, one or more gases from the gas sources 604-608, such as precursors, reactants, carrier gases, and/or purge gases, are introduced into the reaction chamber 602.

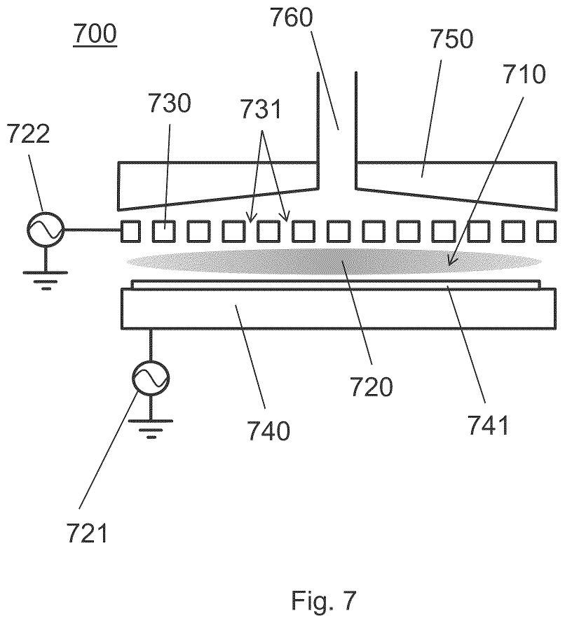

FIG. 7 shows a schematic representation of an embodiment of a system 700 as described herein. It can be used, for example, for forming at least one of a secondary electron reflection layer, a secondary electron generation layer, a glue layer, and an EUV resist. Additionally or alternatively, it can be employed for etching one or more of a gap filling fluid and a material layer. The system 700 comprises a reaction chamber 710 in which a plasma 720 is generated. In particular, the plasma 720 is generated between a showerhead injector 730 and a substrate support 740. This is a direct plasma configuration employing a capacitively coupled plasma.

In the configuration shown, the system 700 comprises two alternating current (AC) power sources: a high frequency power source 721 and a low frequency power source 722. In the configuration shown, the high frequency power source 721 supplies radio frequency (RF) power to the showerhead injector, and the low frequency power source 722 supplies an alternating current signal to the substrate support 740. The radio frequency power can be provided, for example, at a frequency of 13.56 MHz or higher, e.g. at a frequency of at least 100 kHz to at most 50 MHz, or at a frequency of at least 50 MHz to at most 100 MHz, or at a frequency of at least 100 MHz to at most 200 MHz, or at a frequency of at least 200 MHz to at most 500 MHz, or at a frequency of at least 500 MHz to at most 1000 MHz, or at a frequency of at least 1000 MHz to at most 2000 MHz. The low frequency alternating current signal can be provided, for example, at a frequency of 2 MHz or lower, such as at a frequency of at least 100 kHz to at most 200 kHz, or at a frequency of at least 200 kHz to at most 500 kHz, or at a frequency of at least 500 kHz to at most 1000 kHz, or at a frequency of at least 1000 kHz to at most 2000 kHz. Process gas comprising precursor, reactant, or both, is provided through a gas line 760 to a conical gas distributor 750. The process gas then passes through holes 731 in the showerhead injector 730 to the reaction chamber 710.

Whereas the high frequency power source 721 is shown as being electrically connected to the showerhead injector, and the low frequency power source 722 is shown as being electrically connected to the substrate support 740, other configurations are possible as well. For example, in some embodiments (not shown), both the high frequency power source and the low frequency power source can be electrically connected to the showerhead injector; or both the high frequency power source and the low frequency power source can be electrically connected to the substrate support; or the high frequency power source can be electrically connected to the substrate support, and the low frequency power source can be electrically connected to the showerhead injector.

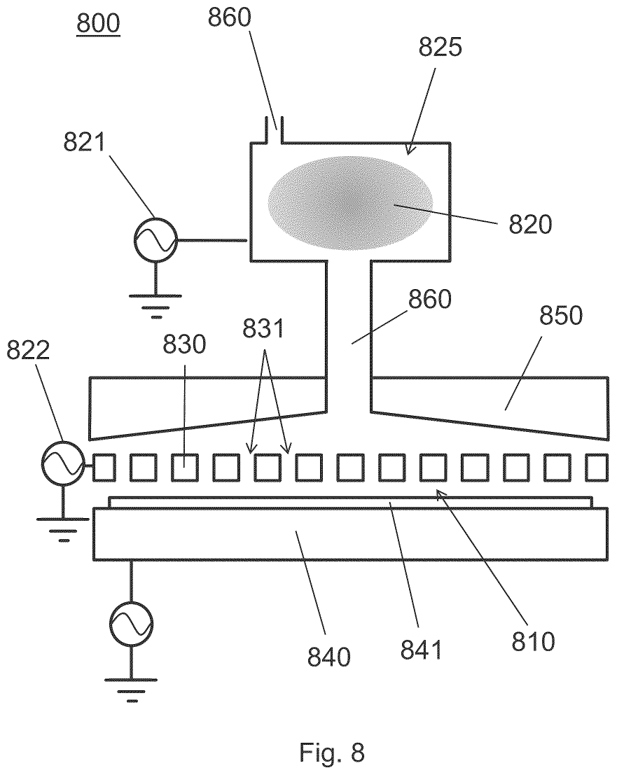

FIG. 8 shows a schematic representation of another embodiment of a system 800 as described herein. It can be used, for example, for forming at least one of a secondary electron generation layer, a glue layer, and an EUV resist. The configuration of FIG. 8 can be described as an indirect plasma system. The sub-system 800 comprises a reaction chamber 810 which is separated from a plasma generation space 825 in which a plasma 820 is generated. In particular, the reaction chamber 810 is separated from the plasma generation space 825 by a showerhead injector, and the plasma 820 is generated between the showerhead injector 830 and a plasma generation space ceiling 826.

In the configuration shown, the sub-system 800 comprises three alternating current (AC) power sources: a high frequency power source 821 and two low frequency power sources 822, 823: a first low frequency power source 822 and a second low frequency power source 823. In the configuration shown, the high frequency power source 821 supplies radio frequency (RF) power to the plasma generation space ceiling, the first low frequency power source 822 supplies an alternating current signal to the showerhead injector 830, and the second low frequency power source 823 supplies an alternating current signal to the substrate support 840. A substrate 841 is provided on the substrate support 840. The radio frequency power can be provided, for example, at a frequency of 13.56 MHz or higher. The low frequency alternating current signal of the first and second low frequency power sources 822, 823 can be provided, for example, at a frequency of 2 MHz or lower.

Process gas comprising precursor, reactant, or both, can be provided through a gas line 860 that passes through the plasma generation space ceiling 826, to the plasma generation space 825. Active species such as ions and radicals generated by the plasma 825 from the process gas pass through holes 831 in the showerhead injector 830 to the reaction chamber 810.

FIG. 14 shows a schematic representation of another embodiment of a sub-system 900 as described herein. It can be used, for example, for forming at least one of a secondary electron generation layer, a glue layer, and an EUV resist. The configuration of FIG. 9 can be described as a remote plasma system. The sub-system 900 comprises a reaction chamber 910 which is operationally connected to a remote plasma source 925 in which a plasma 920 is generated. Any sort of plasma source can be used as a remote plasma source 925, for example, an inductively coupled plasma, a capacitively coupled plasma, or a microwave plasma.

In particular, active species are provided from the plasma source 925 to the reaction chamber 910 via an active species duct 960, to a conical distributor 950, through holes 931 in a shower plate injector 930, to the reaction chamber 910. Thus, active species can be provided to the reaction chamber in a uniform way.

In the configuration shown, the sub-system 900 comprises three alternating current AC power sources: a high frequency power source 921 and two low frequency power sources 922, 1423: a first low frequency power source 922 and a second low frequency power source 923. In the configuration shown, the high frequency power source 921 supplies radio frequency (RF power to the plasma generation space ceiling, the first low frequency power source 922 supplies an alternating current signal to the showerhead injector 930, and the second low frequency power source 923 supplies an alternating current signal to the substrate support 940. A substrate 941 is provided on the substrate support 940. The radio frequency power can be provided, for example, at a frequency of 13.56 MHz or higher. The low frequency alternating current signal of the first and second low frequency power sources 922, 1423 can be provided, for example, at a frequency of 2 MHz or lower.

In some embodiments (not shown, an additional high frequency power source can be electrically connected to the substrate support. Thus, a direct plasma can be generated in the reaction chamber.

Process gas comprising precursor, reactant, or both, is provided to the plasma source 925 by means of a gas line 960. Active species such as ions and radicals generated by the plasma 925 from the process gas are guided to the reaction chamber 910.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

1. A structure comprising a substrate, a secondary electron generation layer, and an extreme ultraviolet (EUV) resist, the secondary electron generation layer being disposed between the substrate and the EUV resist, wherein the secondary electron generation layer comprises hafnium oxide (HfO₂).

2. The structure according to claim 1, wherein the secondary electron generation layer has a thickness of at least 1 nm to at most 5 nm.

3. The structure according to claim 1, wherein the secondary electron generation layer further comprises one or more EUV absorbing elements selected from the list consisting of iodine (I), tellurium (Te), cesium (Cs), antimony (Sb), tin (Sn), indium (In), bismuth (Bi), silver (Ag), lead (Pb), gold (Au), platinum (Pt), iridium (Ir), manganese (Mn), iron (Fe), cobalt (Co), nickel (Ni), copper (Cu), zinc (Zn), gallium (Ga), germanium (Ge), and arsenic (As).

4. The structure according to claim 1, wherein the secondary electron generation layer contains at least 15 atomic percent hafnium.

5. The structure according to claim 1, further comprising a glue layer positioned between the secondary electron generation layer and the EUV resist.

6. The structure according to claim 5, wherein the glue layer comprises silicon, carbon, oxygen, and hydrogen.

7. The structure according to claim 6, wherein the glue layer further comprises nitrogen.

8. A method of forming a structure, the method comprising
providing a substrate to a reaction chamber;
executing a deposition process that comprises exposing the substrate to a hafnium precursor comprising hafnium, the deposition process further comprising exposing the substrate to a reactant, thereby forming a hafnium-containing secondary electron generation layer on the substrate; and,
forming an EUV resist on the substrate.

9. The method according to claim 8, wherein the deposition process comprises a cyclical deposition process, the cyclical deposition process comprising a plurality of cycles, ones from the plurality of cycles comprising a hafnium precursor pulse and a reactant pulse, the hafnium precursor pulse comprising exposing the substrate to the hafnium precursor, the reactant pulse comprising exposing the substrate to the reactant, thereby forming a hafnium-containing secondary electron generation layer on the substrate.

10. The method according to claim 8, further comprising forming a glue layer on the substrate, wherein the glue layer is formed on the hafnium-containing secondary electron generation layer, and wherein the EUV resist is formed on the glue layer.

11. The method according to claim 8, wherein the hafnium precursor comprises one or more alkylamine ligands.

12. The method according to claim 11, wherein the hafnium precursor comprises tetrakis(ethylmethylamino)hafnium.

13. The method according to claim 8, wherein the reactant comprises an oxygen reactant, the oxygen reactant comprising oxygen.

14. The method according to claim 13, wherein the oxygen reactant comprises ozone.

15. The method according to claim 14, wherein the oxygen reactant comprises water.

16. The method according to claim 9, wherein ones from the plurality of cycles further comprise generating a plasma and exposing the substrate to one or more active species generated in the plasma.

17. The method according to claim 16, wherein exposing the substrate to one or more active species generated in the plasma occurs at least partially simultaneously with the reactant pulse and wherein the reactant comprises the one or more active species, the active species comprising at least one of ions and radicals.

18. The method according to claim 8, wherein the deposition process occurs thermally.

19. The method according to claim 9, wherein ones from the plurality of cycles further comprise an EUV absorbing element pulse, the EUV absorbing element pulse comprising exposing the substrate to an EUV absorbing element precursor, wherein the EUV absorbing element precursor comprises an EUV absorbing element selected from the list consisting iodine (I), tellurium (Te), cesium (Cs), antimony (Sb), tin (Sn), indium (In), bismuth (Bi), silver (Ag), lead (Pb), gold (Au), platinum (Pt), iridium (Ir), manganese (Mn), iron (Fe), cobalt (Co), nickel (Ni), copper (Cu), zinc (Zn), gallium (Ga), germanium (Ge), and arsenic (As).

20. A system comprising a reaction chamber and a controller, wherein the controller is constructed and arranged for causing the system to execute a method according to claim 8.
